(19) United States
(12) Patent Application Publication
(10) Pub. No.: US 2024/0379507 A1
(43) Pub. Date: Nov. 14, 2024

(54) SEMICONDUCTOR DEVICE

(71) Applicant: ROHM CO., LTD., Kyoto-shi (JP)

(72) Inventors: Akinori NII, Kyoto-shi (JP); Hiroaki AOYAMA, Kyoto-shi (JP); Kenji FUJII, Kyoto-shi (JP)

(21) Appl. No.: 18/777,108

(22) Filed: Jul. 18, 2024

Related U.S. Application Data
(63) Continuation of application No. PCT/JP2022/047567, filed on Dec. 23, 2022.

(30) Foreign Application Priority Data
Jan. 20, 2022 (JP) 2022-007110

(51) Int. Cl. H01L 23/495; H01L 23/00

(52) U.S. Cl. CPC H01L 23/49541; H01L 24/16; H01L 24/13; H01L 2224/13564; H01L 2224/1357; H01L 2224/16245; H01L 2924/182

(57) ABSTRACT

A semiconductor device includes a lead, a semiconductor element, a sealing resin, and a first conductive section. The lead includes an obverse surface facing in a thickness direction. The semiconductor element includes a circuit section, an element first surface, and first electrodes on the element first surface. The first electrodes are connected to the obverse surface. The sealing resin covers the lead partially and the semiconductor element. The lead includes first terminal sections and a second terminal section aligned in a first direction crossing the thickness direction. Each first electrode is electrically connected to the circuit section. Each first terminal section is electrically connected to the circuit section via one first electrode. The first conductive section is between the second terminal section and the element first surface and connected to the second terminal section and the element first surface. The first conductive section is insulated from the circuit section.

### TECHNICAL FIELD

The present disclosure relates to a semiconductor device.

### BACKGROUND ART

Various configurations have been proposed for a semiconductor device including a semiconductor element. JP-discloses an example of a conventional A-2020-77694 semiconductor device. The semiconductor device disclosed in this document includes a lead, a semiconductor element, and a sealing resin. The lead has a plurality of terminal sections. The terminal sections are aligned in a direction perpendicular to the thickness direction of the lead. The sealing resin covers a portion of the lead as well as the semiconductor element. The sealing resin has a rectangular shape as viewed in the thickness direction.

In the semiconductor device described in JP-A-2020-77694, the semiconductor element is flip-chip mounted on the lead. The lead has an obverse surface facing a first side in the thickness direction. The semiconductor element has a plurality of electrodes. These electrodes are provided on a side facing the obverse surface of the lead and bonded to the obverse surface via a bonding layer made of, for example, solder. The terminal sections, which are aligned in a direction perpendicular to the thickness direction of the lead as described above, are electrically connected to an internal circuit of the semiconductor element via the electrodes.

However, in the configuration where the semiconductor element is flip-chip mounted as described above, the bonding portion of each electrode to the lead cannot be observed directly, and there is no appropriate means for checking the bonding state of the bonding portion. Further, in the configuration where the terminal sections are aligned in a predetermined direction, an electrode located outermost in the alignment direction of the terminal sections among the plurality of electrodes is closest to a corner of a package made of the sealing resin. In general, an internal stress reaches its maximum at the bonding portion of the electrode located closest to the corner of the package, and there is concern that a stress fracture may occur depending on the bonding state of the bonding portion.

### BRIEF DESCRIPTION OF THE DRAWINGS

FIG. 1 is a perspective view showing a semiconductor device according to a first embodiment of the present disclosure.

FIG. 2 is a plan view (seen through a sealing resin) showing the semiconductor device of FIG. 1.

FIG. 3 is a plan view (seen through a semiconductor element and the sealing resin) showing the semiconductor device of FIG. 1.

FIG. 4 is a bottom view showing the semiconductor device of FIG. 1.

FIG. 5 is a front view showing the semiconductor device of FIG. 1.

FIG. 6 is a rear view showing the semiconductor device of FIG. 1.

FIG. 7 is a right-side view showing the semiconductor device of FIG. 1.

FIG. 8 is a left-side view showing the semiconductor device of FIG. 1.

FIG. 9 is a cross-sectional view along line IX-IX in FIG. 3.

FIG. 10 is a cross-sectional view along line X-X in FIG. 3.

FIG. 11 is a cross-sectional view along line XI-XI in FIG. 3.

FIG. 12 is a cross-sectional view along line XII-XII in FIG. 3.

FIG. 13 is a partially enlarged view of FIG. 11.

FIG. 14 is an enlarged cross-sectional view similar to FIG. 11, showing a state where the semiconductor element is mounted so as to be inclined relative to a lead.

FIG. 15 is a plan view similar to FIG. 3, showing a semiconductor device according to a variation of the first embodiment.

FIG. 16 is a cross-sectional view along line XVI-XVI in FIG. 15.

FIG. 17 is a plan view similar to FIG. 3, showing a semiconductor device according to a second embodiment of the present disclosure.

### DETAILED DESCRIPTION OF EMBODIMENTS

The following describes preferred embodiments of the present disclosure in detail with reference to the drawings. The terms such as “first”, “second” and “third” in the present disclosure are used merely as labels, and are not intended to impose orders on the elements accompanied with these terms.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Further, the phrase “an object A overlaps with an object B as viewed in a certain direction” includes, unless otherwise specified, “an object A overlaps with the entirety of an object B” and “an object A overlaps with a portion of an object B”.

### First Embodiment

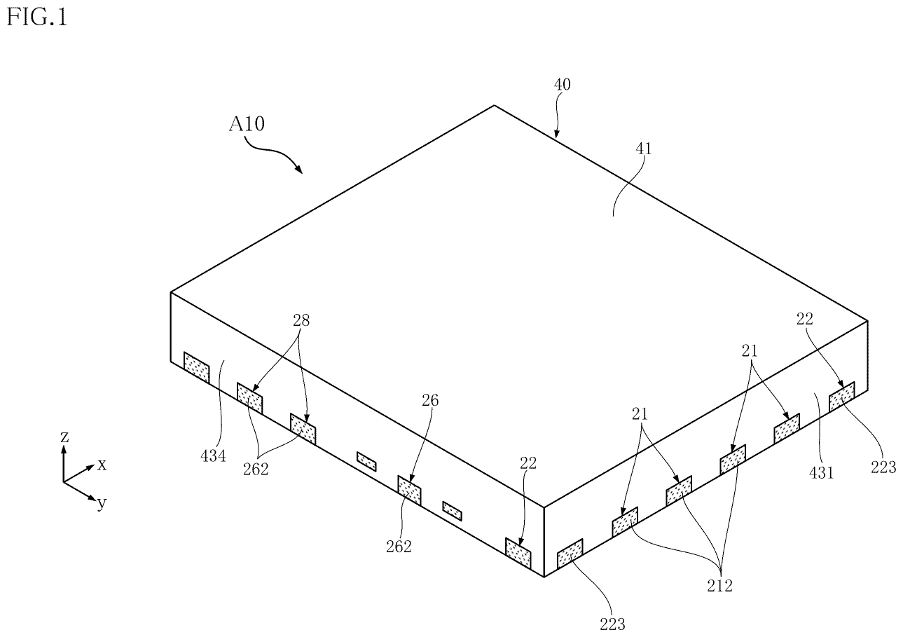

The following describes a semiconductor device according to a first embodiment of the present disclosure, with reference to FIGS. 1 to 13. A semiconductor device A10 of the present embodiment includes a lead 1, a semiconductor element 3, a sealing resin 4, and first conductive sections 6. The lead 1 includes a main section 10, a plurality of first terminal sections 21, two second terminal sections 22, a terminal section 25, two terminal sections 26, a plurality of terminal sections 27, and a plurality of terminal sections 28. The sealing resin 4 has a rectangular shape in plan view. As shown in FIG. 1, the package type of the semiconductor device A10 is a QFN (Quad For Non-Lead Package). The semiconductor element 3 is not limited a specific configuration, and may be a flip-chip LSI (Large Scale Integration). In the present embodiment, the semiconductor element 3 is a flip-chip LSI having a switching circuit 321 and a control circuit 322 inside (details of these circuits are described below). In the semiconductor device A10, the switching circuit 321 converts DC power (voltage) into AC power (voltage). For example, the semiconductor device A10 is used for an element of a DC/DC converter circuit.

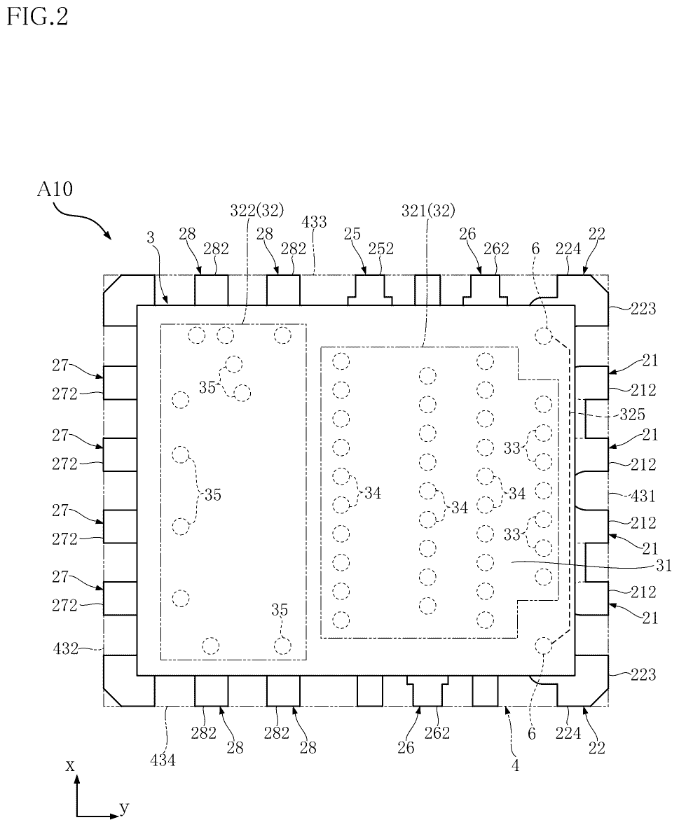

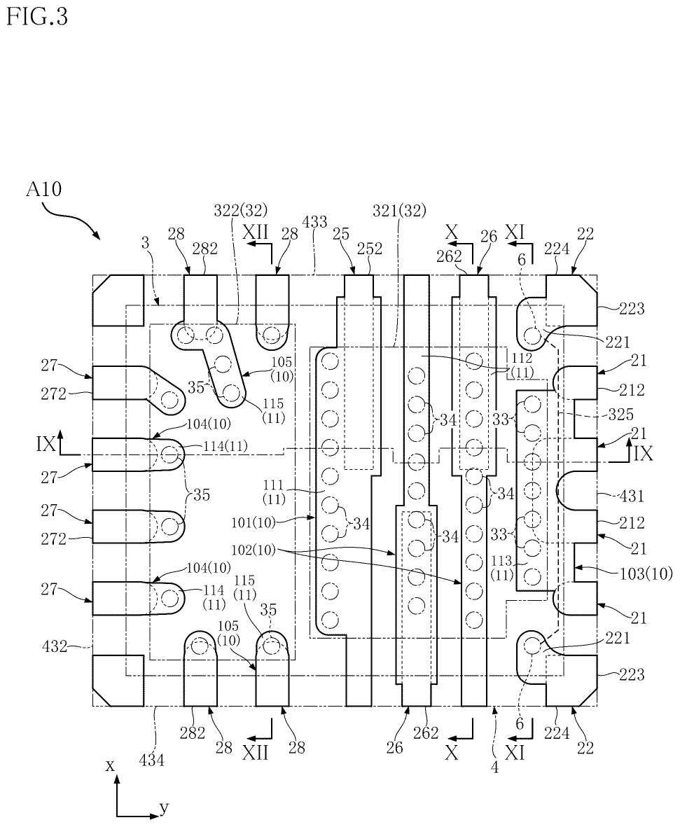

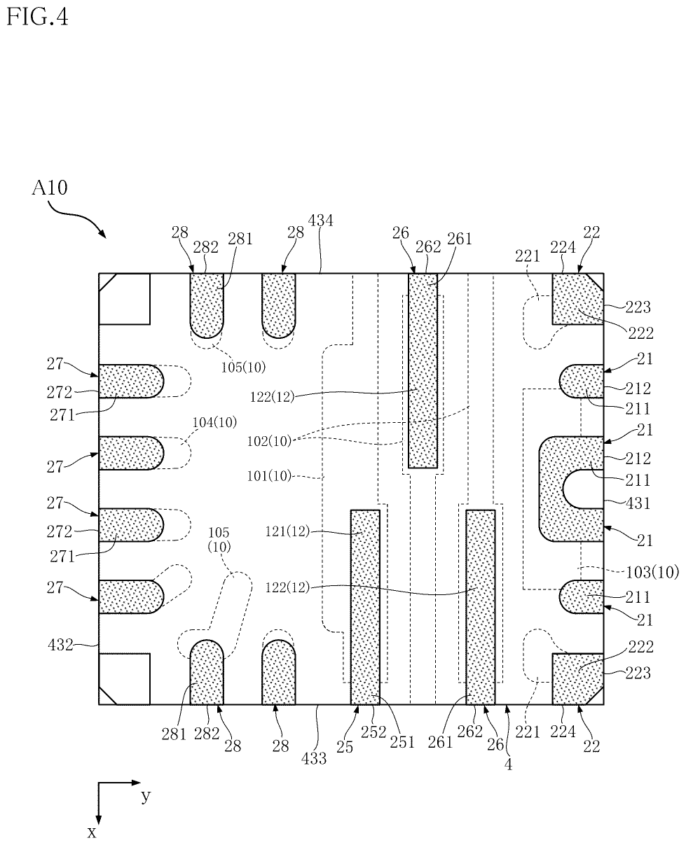

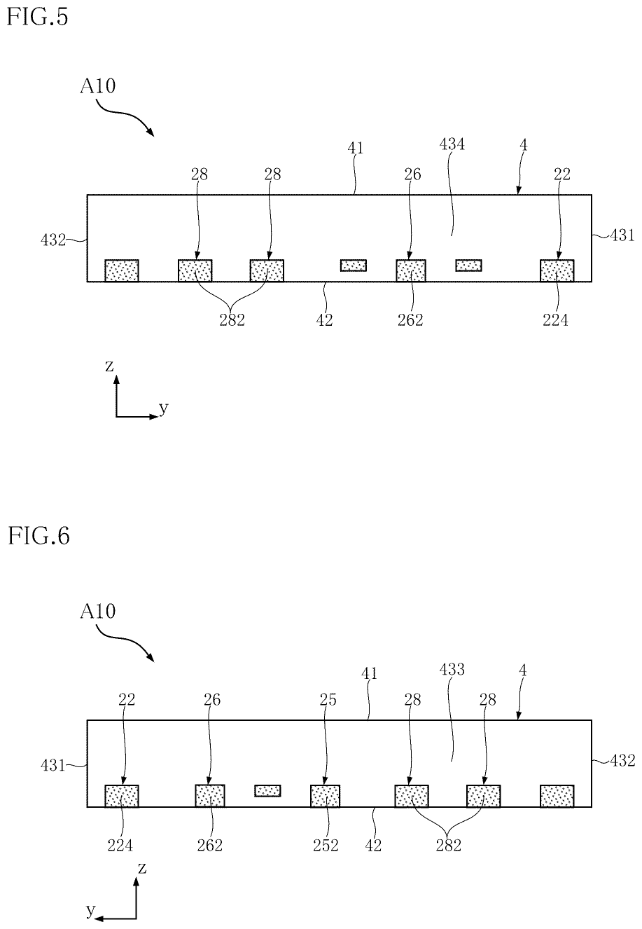

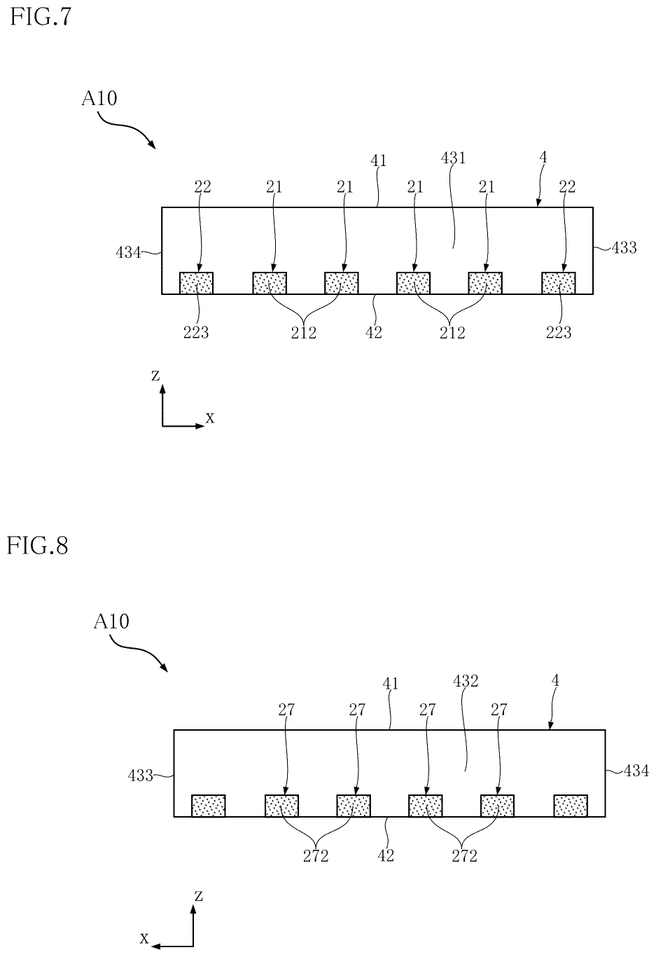

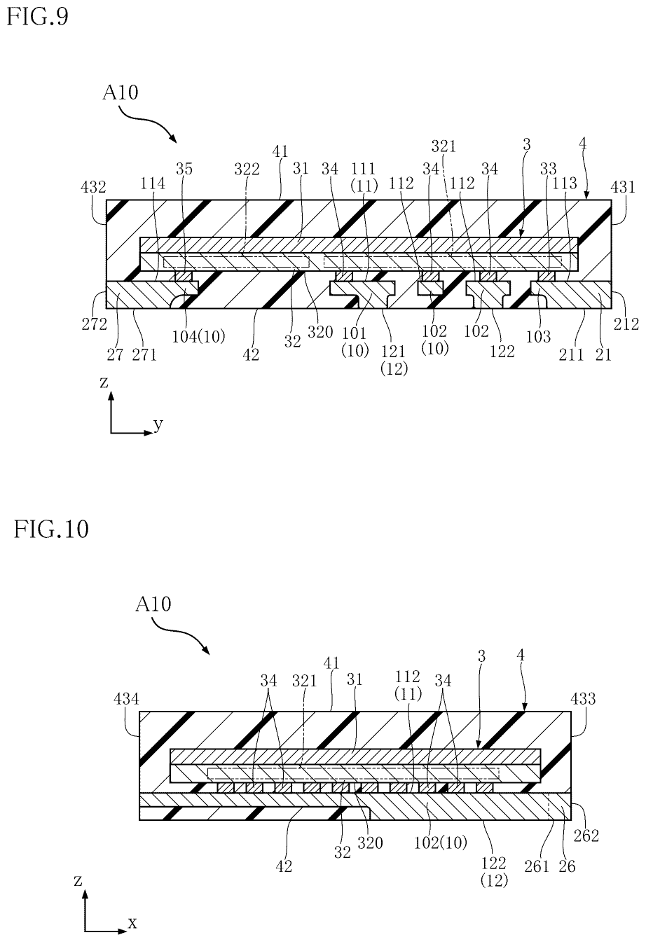

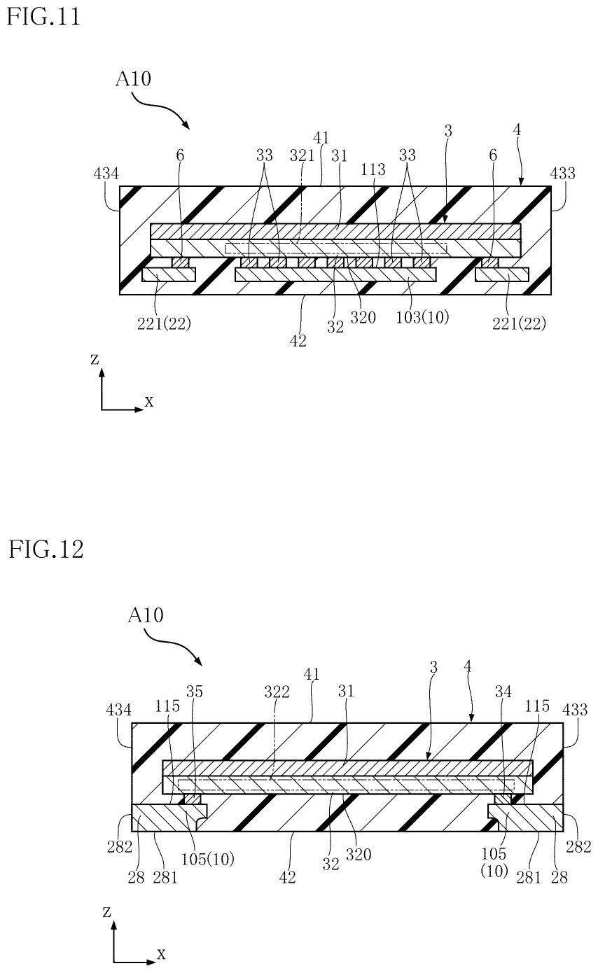

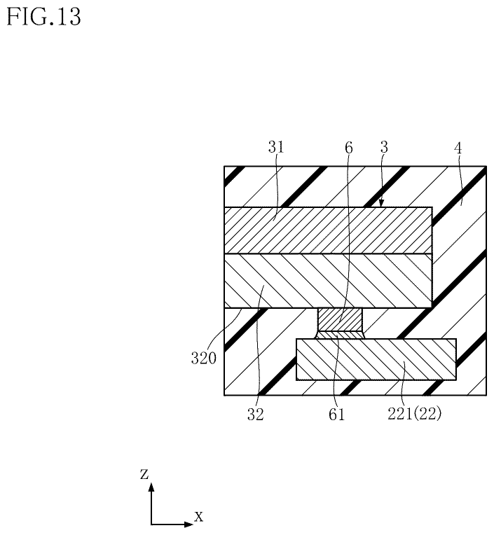

FIG. 1 is a perspective view showing the semiconductor device A10. FIG. 2 is a plan view showing the semiconductor device A10. FIG. 3 is a plan view showing the semiconductor device A10. FIG. 4 is a bottom view showing the semiconductor device A10. FIG. 5 is a front view showing the semiconductor device A10. FIG. 6 is a rear view showing the semiconductor device A10. FIG. 7 is a right-side view showing the semiconductor device A10. FIG. 8 is a left-side view showing the semiconductor device A10. FIG. 9 is a cross-sectional view along line IX-IX in FIG. 3. FIG. 10 is a cross-sectional view along line X-X in FIG. 3. FIG. 11 is a cross-sectional view along line XI-XI in FIG. 3. FIG. 12 is a cross-sectional view along line XII-XII in FIG. 3. FIG. 13 is a partially enlarged view of FIG. 11. For convenience of understanding, FIG. 2 shows the sealing resin 4 in phantom. For convenience of understanding, FIG. 3 shows the semiconductor element 3 and the sealing resin 4 in phantom. In these figures, the semiconductor element 3 and the sealing resin 4 are indicated by imaginary lines (two-dot chain lines).

In the description of the semiconductor device A10, the thickness direction of the main section 10 is referred to as a “thickness direction z”. A direction (the vertical direction in FIG. 2) perpendicular to the thickness direction z is referred to as a “first direction x”. The direction (the horizontal direction in FIG. 2) perpendicular to the thickness direction z and the first direction x is referred to as a “second direction y”. As shown in FIGS. 1 and 2, the semiconductor device A10 has a rectangular shape as viewed in the thickness direction z (in plan view).

Sections (the main section 10, the first terminal sections 21, the two second terminal sections 22, the terminal section 25, the two terminal sections 26, the terminal sections 27, and the terminal sections 28) of the lead 1 are formed from the same lead frame. The lead frame is not limited to a particular material, and may be made of copper (Cu) or a copper alloy, for example.

As shown in FIGS. 3 and 9 to 12, the main section 10 supports the semiconductor element 3. At least a portion of the main section 10 is covered with the sealing resin 4. In the present embodiment, the main section 10 has an obverse surface 11 and a reverse surface 12. The obverse surface 11 faces a first side in the thickness direction z, and faces the semiconductor element 3. The reverse surface 12 faces the opposite side from the obverse surface 11 (a second side in the thickness direction z). The obverse surface 11 is covered with the sealing resin 4. The reverse surface 12 is exposed from the sealing resin 4.

In the present embodiment, the main section 10 includes a first main section 101, two second main sections 102, a third main section 103, a plurality of fourth main sections 104, and a plurality of fifth main sections 105.

The obverse surface 11 has a first obverse surface 111, second obverse surfaces 112, a third obverse surface 113, fourth obverse surfaces 114, and fifth obverse surfaces 115. Each of the first obverse surface 111 to the fifth obverse surfaces 115 belongs to one of the first main section 101 to the fifth main sections 105.

The reverse surface 12 has a first reverse surface 121 and second reverse surfaces 122. Each of the first reverse surface 121 and the second reverse surfaces 122 belongs to one of the first main section 101 and the second main sections 102.

As shown in FIG. 3, the first main section 101 is located at the center (or substantially at the center) of the semiconductor device A10 in the second direction y, and extends in the first direction x. The first main section 101 is an input terminal to which the DC power (voltage) to be converted in the semiconductor device A10 is inputted. The first main section 101 is a positive electrode (P terminal). As shown in FIGS. 3, 4, and 9, the first main section 101 has the first obverse surface 111 and the first reverse surface 121. The semiconductor element 3 is supported by the first obverse surface 111. The first main section 101 has a portion exposed from the sealing resin 4 to the second side in the thickness direction z, and the exposed portion includes the first reverse surface 121.

As shown in FIG. 3, the two second main sections 102 are located on a first side (right side in the figure) of the semiconductor device A10 in the second direction y, and are spaced apart from each other in the second direction y. The two second main sections 102 are adjacent to each other in the second direction y and extend in the first direction x. Each of the two second main sections 102 outputs the AC power (voltage) resulting from the power conversion by the switching circuit 321 configured in the semiconductor element 3.

As shown in FIGS. 3, 4, 9, and 10, each of the second main sections 102 has a second obverse surface 112 and a second reverse surface 122. The semiconductor element 3 is supported by the second obverse surfaces 112. Each of the second main sections 102 has a portion exposed from the sealing resin 4 to the second side in the thickness direction z, and the exposed portion includes a second reverse surface 122.

As shown in FIG. 3, the third main section 103 is located near the end of the semiconductor device A10 on the first side (the right side in the figure) in the second direction y, and is adjacent to one of the second main sections 102 such that the third main section 103 is on the first side in the second direction y relative to the second main section 102. The third main section 103 extends in the first direction x. The third main section 103 is an input terminal to which the DC power (voltage) to be converted in the semiconductor device A10 is inputted. The third main section 103 is a negative electrode (N terminal).

As shown in FIGS. 3, 9, and 11, the third main section 103 has the third obverse surface 113. The semiconductor element 3 is supported by the third obverse surface 113.

As shown in FIG. 3, the fourth main sections 104 are offset from the first main section 101 to a second side (the left side in the figure) in the second direction y. The fourth main sections 104 are spaced apart from each other in the first direction x. Each of the fourth main sections 104 receives power (voltage) for driving the control circuit 322, or receives an electric signal to be transmitted to the control circuit 322, for example.

As shown in FIGS. 3 and 9, each of the fourth main sections 104 has a fourth obverse surface 114. The semiconductor element 3 is supported by the fourth obverse surfaces 114.

As shown in FIG. 3, the fifth main sections 105 are offset from the first main section 101 to the second side (the left side in the figure) in the second direction y. Some of the fifth main sections 105 are located on the first side (the upper side in the figure) of the semiconductor device A10 in the first direction x. The rest of the fifth main sections 105 are located on a second side (the lower side in the figure) of the semiconductor device A10 in the first direction x. Each of the fifth main sections 105 receives an electric signal to be transmitted to the control circuit 322, for example.

As shown in FIGS. 3 and 12, each of the fifth main sections 105 has a fifth obverse surface 115. The semiconductor element 3 is supported by the fifth obverse surfaces 115.

The obverse surface 11 (the first obverse surface 111 to the fifth obverse surfaces 115) of the main section 10 (the first main section 101 to the fifth main sections 105), which supports the semiconductor element 3, may be plated with silver (Ag). Further, the reverse surface 12 (the first reverse surface 121 and the second reverse surfaces 122) exposed from the sealing resin 4 may be plated with tin (Sn). Instead of tin plating, plating with nickel (Ni), palladium (Pd), and gold (Au) may be performed in this order to form a laminate of metal plating layers. In FIGS. 1 and 4 to 8, the portions of the lead 1 (the main section 10, the first terminal sections 21, the two second terminal sections 22, the terminal section 25, the two terminal sections 26, the terminal sections 27, and the terminal sections 28) exposed from the sealing resin 4 are indicated by a plurality of dotted areas.

As shown in FIG. 3, the first terminal sections 21 are aligned in the first direction x. In the present embodiment, the first terminal sections 21 are arranged at the end (the right end in the figure) of the semiconductor device A10 (the sealing resin 4) on the first side in the second direction y. The first terminal sections 21 are continuous with the third main section 103. The first terminal sections 21 have the same configuration. Accordingly, the configuration of one of the first terminal sections 21 in the semiconductor device A10 will be described below as a representative.

As shown in FIGS. 3, 4, 7, and 9, a first terminal section 21 has a first mounting surface 211 and a first side surface 212. The first mounting surface 211 faces the second side in the thickness direction z. The first side surface 212 faces the first side in the second direction y. In the present embodiment, the first side surface 212 is continuous with the first mounting surface 211 and flush with the surrounding. The first mounting surface 211 and the first side surface 212 are exposed from the sealing resin 4.

In each of the first terminal sections 21, the first mounting surface 211 and the first side surface 212 exposed from the sealing resin 4 may be plated with tin. Instead of tin plating, plating with nickel, palladium, and gold may be performed in this order to form a laminate of metal plating layers.

As shown in FIG. 3, each of the second terminal sections 22 is located closer to an end of the sealing resin 4 in the first direction x than are the first terminal sections 21. In the present embodiment, the two second terminal sections 22 are arranged on the first side and the second side in the first direction x, respectively, relative to the first terminal sections 21. Of the four corners of the sealing resin 4 having a rectangular shape as viewed in the thickness direction z, the two second terminal sections 22 are arranged at two corners located on the first side in the second direction y and on the respective sides in the first direction X.

As shown in FIGS. 3 to 7 and 11, each of the second terminal sections 22 has an extending portion 221, a second mounting surface 222, a second side surface 223, and a third side surface 224. The extending portion 221 extends toward the inside of the sealing resin 4 from an end of the sealing resin 4 in the first direction x and an end of the sealing resin 4 in the second direction y. The extending portion 221 (the second terminal section 22) is connected to a first conductive section 6. The second mounting surface 222 faces the second side in the thickness direction z. The second side surface 223 faces the same side as the first side surfaces 212 of the first terminal sections 21, and faces the first side in the second direction y. The third side surface 224 faces either the first side in the first direction x or the second side in the first direction x. In the present embodiment, the second side surface 223 is continuous with the second mounting surface 222 and flush with the surrounding. The third side surface 224 is continuous with the second mounting surface 222 and the second side surface 223 and flush with the surrounding. The second mounting surface 222, the second side surface 223, and the third side surface 224 are exposed from the sealing resin 4.

In each of the two second terminal sections 22, the upper surface (the surface facing the first side in the thickness direction z) of the extending portion 221 to which a first conductive section 6 is connected may be plated with silver. Further, the second mounting surface 222, the second side surface 223, and the third side surface 224 exposed from the sealing resin 4 may be plated with tin. Instead of tin plating, plating with nickel, palladium, and gold may be performed in this order to form a laminate of metal plating layers.

As shown in FIG. 3, the terminal section 25 is arranged at the end (the upper end in the figure) of the semiconductor device A10 on the first side in the first direction x. The terminal section 25 is continuous with the first main section 101. As shown in FIGS. 3, 4, and 6, the terminal section 25 has a mounting surface 251 and a side surface 252. The mounting surface 251 faces the second side in the thickness direction z. The side surface 252 faces the first side in the first direction x. In the present embodiment, the side surface 252 is continuous with the mounting surface 251 and flush with the surrounding. The mounting surface 251 and the side surface 252 are exposed from the sealing resin 4.

As shown in FIG. 3, the two terminal sections 26 are arranged at the end (the upper end in the figure) of the semiconductor device A10 on the first side in the first direction x and the end (the lower end of the figure) of the semiconductor device A10 on the second side in the first direction x, respectively. The two terminal sections 26 are continuous with the two second main sections 102, respectively. As shown in FIGS. 3 to 6 and 10, each of the terminal sections 26 has a mounting surface 261 and a side surface 262. The mounting surface 261 faces the second side in the thickness direction z. The side surface 262 faces either the first side in the first direction x and the second side in the first direction x. In the present embodiment, each of the side surfaces 262 is continuous with one of the mounting surfaces 261 and flush with the surrounding. The mounting surface 261 and the side surface 262 are exposed from the sealing resin 4.

As shown in FIG. 3, the terminal sections 27 are arranged at the end (the left end in the figure) of the semiconductor device A10 on the second side in the second direction y. Each of the terminal sections 27 is continuous with one of the fourth main sections 104. As shown in FIGS. 3, 4, 8, and 9, each of the terminal sections 27 has a mounting surface 271 and a side surface 272. The mounting surface 271 faces the second side in the thickness direction z. The side surface 272 faces the second side in the second direction y. In the present embodiment, the side surface 272 is continuous with the mounting surface 271 and flush with the surrounding. The mounting surface 271 and the side surface 272 are exposed from the sealing resin 4.

As shown in FIG. 3, the terminal sections 28 are arranged at the end (the upper end in the figure) of the semiconductor device A10 on the first side in the first direction x and at the end (the lower end in the figure) of the semiconductor device A10 on the second side in the first direction x. Each of the terminal sections 28 is continuous with one of the fifth main sections 105. As shown in FIGS. 3 to 6 and 12, each of the terminal sections 28 has a mounting surface 281 and a side surface 282. The mounting surface 281 faces the second side in the thickness direction z. The side surface 282 faces either the first side in the first direction x and the second side in the first direction x. In the present embodiment, the side surface 282 is continuous with the mounting surface 281 and flush with the surrounding. The mounting surface 281 and the side surface 282 are exposed from the sealing resin 4.

In the terminal section 25, the two terminal sections 26, the terminal sections 27, and the terminal sections 28, the portions (the mounting surfaces 251, 261, 271, and 281 and the side surfaces 252, 262, 272, and 282) exposed from the sealing resin 4 may be plated with tin. Instead of tin plating, plating with nickel, palladium, and gold may be performed in this order to form a laminate of metal plating layers.

The semiconductor element 3 has a semiconductor substrate 31, a semiconductor layer 32, a plurality of first electrodes 33, a plurality of electrodes 34, and a plurality of electrodes 35. As shown in FIGS. 9 to 12, the semiconductor substrate 31 supports the semiconductor layer 32, the first electrodes 33, the electrodes 34, and the electrodes 35, which are located below the semiconductor substrate 31. The constituent material of the semiconductor substrate 31 is silicon (Si) or silicon carbide (Sic).

The semiconductor layer 32 stacked the is on semiconductor substrate 31 on the side opposite from the obverse surface 11 in the thickness direction Z. The semiconductor layer 32 has an element first surface 320. The element first surface 320 faces the second side in the thickness direction z and is opposed to the obverse surface 11 in the thickness direction z. The semiconductor layer 32 contains multiple kinds of p-type semiconductors and n-type semiconductors based on the difference in the amounts of elements to be doped. The semiconductor layer 32 includes 322 the switching circuit 321 and the control circuit electrically connected to the switching circuit 321. The switching circuit 321 may be a metal-oxide-semiconductor field-effect transistor (MOSFET) or an insulated gate bipolar transistor (IGBT). In the example of the semiconductor device A10, the switching circuit 321 is divided into two areas, i.e., a high-voltage area (upper arm circuit) and a low-voltage area (lower arm circuit). Each of the areas is formed with a single n-channel MOSFET. The control circuit 322 includes a gate driver for driving the switching circuit 321 and a bootstrap circuit corresponding to the high-voltage area of the switching circuit 321, and performs control for properly driving the switching circuit 321. Note that the semiconductor layer 32 further includes a wiring layer (not illustrated). The wiring layer electrically connects the switching circuit 321 and the control circuit 322 to each other. The switching circuit 321 and the control circuit 322 are examples of a “circuit section”.

In the present embodiment, the semiconductor element 3 has a first wire 325 provided on the semiconductor layer 32 (see FIGS. 2 and 3). In FIGS. 2 and 3, the path of the first wire 325 is simplified and indicated by a dotted line. The first wire 325 is not electrically connected to any of the switching circuit 321, the control circuit 322, and the wiring layer described above.

As shown in FIGS. 9 to 12, the first electrodes 33, the electrodes 34, and the electrodes 35 are provided on the element first surface 320 that faces the obverse surface 11 (the first obverse surface 111 to the fifth obverse surfaces 115) in the thickness direction z. The first electrodes 33, the electrodes 34, and the electrodes 35 are in contact with the semiconductor layer 32.

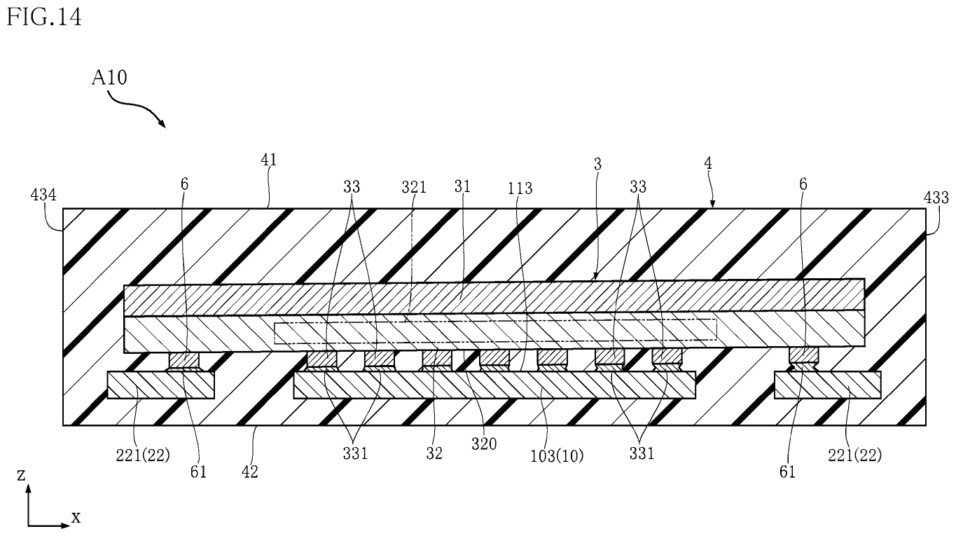

The first electrodes 33 are electrically connected to the switching circuit 321 of the semiconductor layer 32. The first electrodes 33 are connected to the third main section 103. As shown in FIGS. 3 and 11, the first electrodes 33 are aligned in the first direction x. The first electrodes 33 are connected to the third obverse surface 113 of the third main section 103 via a bonding layer (see a bonding layer 331 in FIG. 14) having conductivity such as solder. The third main section 103 is continuous with the first terminal sections 21. As a result, each of the first terminal sections 21 is electrically connected to the switching circuit 321 (the circuit section) via at least one of the first electrodes 33.

The electrodes 34 are electrically connected to the switching circuit 321 of the semiconductor layer 32. Each of the electrodes 34 is connected to one of the first obverse surface 111 of the first main section 101 and the second obverse surfaces 112 of the two second main sections 102. As with the first electrodes 33, the electrodes 34 are connected to the first obverse surface 111 (the second obverse surfaces 112) via a bonding layer (not illustrated) having conductivity such as solder. As a result, the first main section 101 and the two second main sections 102 are electrically connected to the switching circuit 321.

The electrodes 35 are electrically connected to the control circuit 322 of the semiconductor layer 32. Each of the electrodes 35 is connected to one of the fourth obverse surfaces 114 of the fourth main sections 104 and the fifth obverse surfaces 115 of the fifth main sections 105. As with the first electrodes 33, the electrodes 35 are connected to the fourth obverse surfaces 114 (the fifth obverse surfaces 115) via a bonding layer (not illustrated) having conductivity such as solder. As a result, the fourth main sections 104 and the fifth main sections 105 are electrically connected to the control circuit 322. The constituent material of the first electrodes 33, the electrodes 34, and the electrodes 35 contains copper, for example.

As shown in FIG. 11, each of the first conductive sections 6 is located between the extending portion 221 of one of the second terminal sections 22 and the element first surface 320 of the semiconductor element 3. The first conductive sections 6 are connected to the respective extending portions 221 (second terminal sections 22) and the element first surface 320. As shown in FIG. 13, each of the first conductive sections 6 is connected to the upper surface (the surface facing the first side in the thickness direction z) of an extending portion 221 via a bonding layer 61 having conductivity such as solder. As shown in FIGS. 3 and 11, in the present embodiment, two first conductive sections 6 are each provided between one of the two second terminal sections 22 and the element first surface 320 of the semiconductor layer 32. Each of the two first conductive sections 6 overlaps with the first electrodes 33 as viewed in the first direction x.

The two first conductive sections 6 are not electrically connected to any of the switching circuit 321, the control circuit 322, and the wiring layer described above in the semiconductor layer 32. Accordingly, the two first conductive sections 6 are insulated from the switching circuit 321 and the control circuit 322 (the circuit section). On the other hand, each of the two first conductive sections 6 is electrically connected to the first wire 325 in the semiconductor layer 32.

As shown in FIGS. 5 to 8, the sealing resin 4 has a resin obverse surface 41, a resin reverse surface 42, two first resin side surfaces 431 and 432, and two second resin side surfaces 433 and 434. The constituent material of the sealing resin 4 is a black epoxy resin, for example.

As shown in FIGS. 9 to 12, the resin obverse surface 41 faces the same side as the obverse surface 11 (the first obverse surface 111 to the fifth obverse surfaces 115) in the thickness direction z. As shown in FIGS. 5 to 8, the resin reverse surface 42 faces the opposite side from the resin obverse surface 41. As shown in FIGS. 4 and 9 to 12, the first reverse surface 121 of the first main section 101, the second reverse surfaces 122 of the second main sections 102, the first mounting surfaces 211 of the first terminal sections 21, the second mounting surfaces 222 of the second terminal sections 22, the mounting surface 251 of the terminal section 25, the mounting surfaces 261 of the terminal sections 26, the mounting surfaces 271 of the terminal sections 27, and the mounting surfaces 281 of the terminal sections 28 are exposed from the resin reverse surface 42 (the sealing resin 4).

As shown in FIGS. 5 and 6, the first resin side surface 431 is located at the end of the sealing resin 4 on the first side in the second direction y, and faces the first side in the second direction y. The first resin side surface 431 is connected to the resin obverse surface 41 and the resin reverse surface 42. As shown in FIGS. 4 and 9, the first side surface 212 of each first terminal section 21 arranged at the end of the semiconductor device A10 on the first side in the second direction y is flush with the first resin side surface 431. As shown in FIGS. 3 and 4, the second side surface 223 of each of the two second terminal sections 22 arranged on the respective ends of the semiconductor device A10 in the first direction x and at the end of the semiconductor device A10 on the first side in the second direction y is flush with the first resin side surface 431.

As shown in FIGS. 5 and 6, the first resin side surface 432 is located at the end of the sealing resin 4 on the second side in the second direction y, and faces the second side in the second direction y. The first resin side surface 432 is connected to the resin obverse surface 41 and the resin reverse surface 42. As shown in FIGS. 4 and 9, the side surface 272 of each terminal section 27 arranged at the end of the semiconductor device A10 on the second side in the second direction y is flush with the first resin side surface 432.

As shown in FIGS. 7 and 8, the second resin side surface 433 is located at the end of the sealing resin 4 on the first side in the first direction x and faces the first side in the first direction x. The second resin side surface 433 is connected to the resin obverse surface 41 and the resin reverse surface 42 . . . . As shown in FIGS. 4, 10, and 12, the side surface 252 of the terminal section 25, the side surface 262 of the terminal section 26, and the side surfaces 282 of the terminal sections 28 arranged at the end of the semiconductor device A10 on the first side in the first direction x are flush with the second resin side surface 433. As shown in FIGS. 3 and 4, the third side surface 224 of the second terminal section 22 arranged at the end of the semiconductor device A10 on the first side in the first direction x and at the end of the semiconductor device A10 on the first side in the second direction y is flush with the second resin side surface 433.

As shown in FIGS. 7 and 8, the second resin side surface 434 is located at the end of the sealing resin 4 on the second side in the first direction x and faces the second side in the first direction x. The second resin side surface 434 is connected to the resin obverse surface 41 and the resin reverse surface 42. As shown in FIGS. 4 and 12, the side surface 262 of the terminal section 26 and the side surface 282 of each terminal section 28 arranged at the end of the semiconductor device A10 on the second side in the first direction x are flush with the second resin side surface 434. As shown in FIGS. 3 and 4, the third side surface 224 of the 22 arranged at the end of the second terminal section semiconductor device A10 on the second side in the first direction x and at the end of the semiconductor device A10 on the first side in the second direction y is flush with the second resin side surface 434.

Next, advantages of the present embodiment will be described.

In the semiconductor device A10, the lead 1 includes the first terminal sections 21 and the second terminal sections 22. The first terminal sections 21 are aligned in the first direction x, and each of the second terminal sections 22 is located closer to an end of the sealing resin 4 in the first direction x than are the first terminal sections 21. The semiconductor element 3 has the element first surface 320 facing the obverse surface 11 of the lead 1 and the first electrodes 33 provided on the element first surface 320. The first electrodes 33 are connected to the third obverse surface 113 (the obverse surface 11), and each of the first terminal sections 21 is electrically connected to the switching circuit 321 (the circuit section) of the semiconductor element 3 via at least one of the first electrodes 33. The semiconductor device A10 further includes the first conductive sections 6. Each of the first conductive sections 6 is located between a second terminal section 22 and the element first surface 320, and is connected to the second terminal section 22 and the element first surface 320. The first conductive sections 6 are insulated from the switching circuit 321 and the control circuit 322 (the circuit section).

According to such a configuration, the first conductive sections 6, which are not electrically connected to the circuit section that performs the function of the semiconductor element 3, are each located closer to a corner of the package made of the sealing resin 4 than are the first electrodes 33. Thus, the internal stress is larger at the bonding portion of each first conductive section 6 to one of the second terminal sections 22 than at the bonding portion of each first electrode 33 to the third main section 103 (the third obverse surface 113). The first conductive sections 6 are not connected to and are insulated from the switching circuit 321 (the circuit section) that performs the function of the semiconductor element 3, and do not constitute an electrically conductive path for the semiconductor element 3. Accordingly, the internal stress at the bonding portion of each first electrode 33 electrically connected to the switching circuit 321 (the circuit section) can be reduced by providing the first conductive sections 6 near some corners of the sealing resin 4. This makes it possible to improve the bonding reliability of the semiconductor element 3 provided by flip-chip mounting.

In the semiconductor device A10, the two second terminal sections 22 are arranged on the first side and the second side in the first direction x, respectively, relative to the first terminal sections 21. Further, the two first conductive sections 6 are each provided between one of the two second terminal sections 22 and the element first surface 320 of the semiconductor layer 32. Such a configuration can reduce the internal stress of the bonding portions of the first electrodes 33 located at the respective ends in the alignment direction (the first direction x) among the plurality of first electrodes 33. This is more preferable for improving the bonding reliability of the semiconductor element 3.

The first electrodes 33 are aligned in the first direction x. Each of the first conductive sections 6 overlaps with the first electrodes 33 as viewed in the first direction X. Such a configuration can efficiently reduce the internal stress of the bonding portions of the first electrodes 33.

As shown in FIG. 14, when the semiconductor element 3 is flip-chip mounted on the lead 1 in a state where the semiconductor element 3 is slightly inclined in the first direction x, the bonding layers 61 of the two first conductive sections 6 flanking the first electrodes 33 in the first direction x exhibit a noticeable change in the bonding state. In the present embodiment, the semiconductor layer 32 (the semiconductor element 3) has the first wire 325 electrically connected to the two first conductive sections 6. With such a configuration, the two second terminal sections 22 respectively connected to the two first conductive sections 6 are used to electrically measure the path consisting of the two first conductive sections 6 and the first wire 325, whereby a change in the bonding state of the bonding portion (the bonding layer 61) of each first conductive section 6 can be detected as a change in resistance value. This makes it possible to check the bonding states of the bonding portions of the two first conductive sections 6 and the bonding portions of the first electrodes 33 arranged between the first conductive sections 6 in the first direction x. This leads to an improvement of the bonding reliability of the semiconductor device A10 having the semiconductor element 3 provided by flip-chip mounting.

### VARIATION OF THE FIRST EMBODIMENT

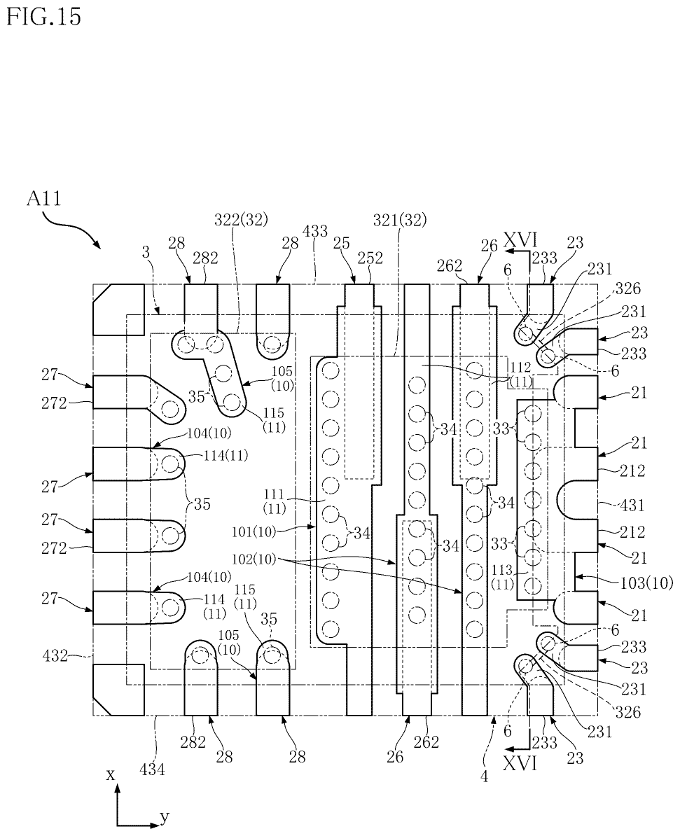

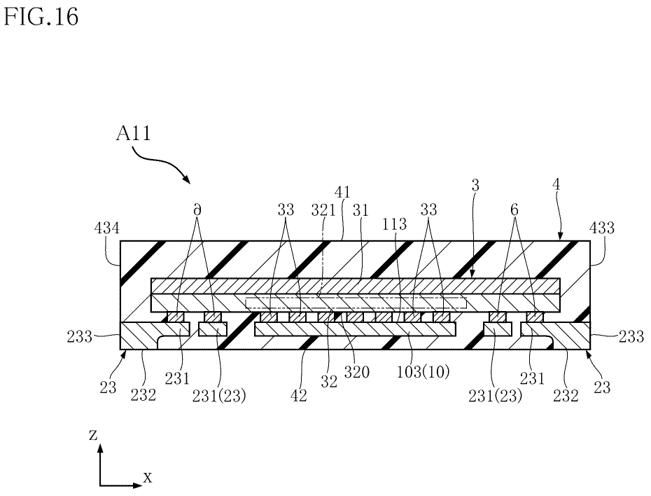

FIGS. 15 and 16 show a semiconductor device A11 according to a variation of the first embodiment. FIG. 15 is a plan view showing the semiconductor device A11. FIG. 16 is a cross-sectional view along line XVI-XVI in FIG. 15. In FIG. 5 and the subsequent drawings, the elements that are identical with or similar to those of the semiconductor device A10 in the above embodiment are designated by the same reference numerals as in the above embodiment, and the descriptions thereof are omitted as appropriate. For convenience of understanding, FIG. 15 shows the semiconductor element 3 and the sealing resin 4 in phantom. In FIG. 15, the semiconductor element 3 and the sealing resin 4 are indicated by imaginary lines (two-dot chain lines).

The semiconductor device A11 of the present variation includes second terminal sections 23 instead of the second terminal sections 22 in the above embodiment, and various changes have been made accordingly. In the present variation, two second terminal sections 23 are arranged near the first terminal sections 21 on the first side in the first direction X. Further, another two second terminal sections 23 are arranged near the first terminal sections 21 on the second side in the first direction x.

As shown in FIGS. 15 and 16, each of the second terminal sections 23 has an extending portion 231, a third mounting surface 232, and a fourth side surface 233. The extending portion 231 extends toward the inside of the sealing resin 4 from an end of the sealing resin 4 in the first direction x and an end of the sealing resin 4 in the second direction y. The extending portion 231 (the second terminal section 23) is connected to a first conductive section 6. The third mounting surface 232 faces the second side in the thickness direction Z. The fourth side surface 233 faces either in the first direction x or in the second direction y. Of the two second terminal sections 23 arranged on the first side in the first direction x with respect to the first terminal sections 21, the fourth side surface 233 of one second terminal section 23 faces the first side in the first direction x, and the fourth side surface 233 of the other second terminal section 23 faces the first side in the second direction y. Of the two second terminal sections 23 arranged on the second side in the first direction x with respect to the first terminal sections 21, the fourth side surface 233 of one second terminal section 23 faces the second side in the first direction x, and the fourth side surface 233 of the other second terminal section 23 faces the first side in the second direction y. In the present variation, each of the fourth side surfaces 233 is connected to one of the third mounting surfaces 232 and flush with the surrounding. The third mounting surfaces 232 and the fourth side surfaces 233 are exposed from the sealing resin 4.

As shown FIGS. 15 and 16, two first conductive sections 6 are each provided between one of the two second terminal sections 23 arranged on the first side in the first direction X with respect to the first terminal sections 21 and the element first surface 320 of the semiconductor layer 32. Further, another two first conductive sections 6 different from the above-described first conductive sections 6 are each provided between one of the two second terminal sections 23 arranged on the second side in the first direction x with respect to the first terminal sections 21 and the element first surface 320 of the semiconductor layer 32.

As shown in FIG. 15, the semiconductor element 3 of the semiconductor device A11 has second wires 326 provided on the semiconductor layer 32 instead of the first wire 325 in the above embodiment. In FIG. 15, the paths of the second wires 326 are simplified and indicated by dotted lines. The second wires 326 are not electrically connected to any of the switching circuit 321, the control circuit 322, and the wiring layer described above. In the present variation, the second wires 326 are provided at two locations on the first side and the second side in the first direction x, corresponding to the two second terminal sections 23 arranged on the first side in the first direction x with respect to the first terminal sections 21 and to the two second terminal sections 23 arranged on the second side in the first direction x with respect to the first terminal sections 21.

The first conductive sections 6 are not electrically connected to any of the switching circuit 321, the control circuit 322, and the wiring layer described above in the semiconductor layer 32. Accordingly, the first conductive sections 6 are insulated from the switching circuit 321 and the control circuit 322 (the circuit section). On the other hand, the two first conductive sections 6 arranged on the first side in the first direction x with respect to the first electrodes 33 are electrically connected to one of the second wires 326 on the semiconductor layer 32. The two first conductive sections 6 arranged on the second side in the first direction x with respect to the first electrodes 33 are electrically connected to the other second wire 326 on the semiconductor layer 32.

According to the semiconductor device A11 in the present variation, the first conductive sections 6, which are not electrically connected to the circuit section that performs the function of the semiconductor element 3, are each located closer to a corner of the package made of the sealing resin 4 than are the first electrodes 33. Thus, the internal stress is larger at the bonding portion of each first conductive section 6 to one of the second terminal sections 23 than at the bonding portion of each first electrode 33 to the third main section 103 (the third obverse surface 113). The first conductive sections 6 are not connected to and are insulated from the switching circuit 321 (the circuit section) that performs the function of the semiconductor element 3, and do not constitute an electrically conductive path for the semiconductor element 3. Accordingly, the internal stress at the bonding portion of each first electrode 33 electrically connected to the switching circuit 321 (the circuit section) can be reduced by providing the first conductive sections 6 near some corners of the sealing resin 4. This makes it possible to improve the bonding reliability of the semiconductor element 3 provided by flip-chip mounting.

In the semiconductor device A11, two second terminal sections 23 are arranged near the first terminal sections 21 on the first side in the first direction x. Further, two first conductive sections 6 are each provided between one of the two second terminal sections 23 and the element first surface 320 of the semiconductor layer 32. The semiconductor layer 32 (the semiconductor element 3) has a second wire 326 electrically connected to the two first conductive sections 6. With such a configuration, the two second terminal sections 23 respectively connected to the two first conductive sections 6 are e used to electrically measure the path consisting of the two first conductive sections 6 and the second wire 326, whereby a change in the bonding state of the bonding portion of each first conductive section 6 can be detected as a change in resistance value. This makes it possible to check the bonding states of the bonding portions of the two first conductive sections 6 located at the corner of the package made of the sealing resin 4 on the first side in the first direction x and on the first side in the second direction y. This leads to an improvement of the bonding reliability of the semiconductor device A11 having the semiconductor element 3 provided by flip-chip mounting.

In the present variation, two second terminal sections 23 are arranged near the first terminal sections 21 on the second side in the first direction x. Further, another two first conductive sections 6 different from the above-described first conductive sections 6 are each provided between one of the two second terminal sections 23 and the element first surface 320 of the semiconductor layer 32. The semiconductor layer 32 (the semiconductor element 3) has a second wire 326 electrically connected to the two first conductive sections 6. With such a configuration, the two second terminal sections 23 respectively connected to the two first conductive sections 6 are used to electrically measure the path of the two first conductive sections 6 and the second wire 326, whereby a change in the bonding state of the bonding portion of each first conductive section 6 can be detected as a change in resistance value. This makes it possible to check the bonding states of the bonding portions of the two first conductive sections 6 located at the corner of the package made of the sealing resin 4 on the second side in the first direction x and on the first side in the second direction y. The semiconductor device A11 also has advantages similar to those of the semiconductor device A10 in the above embodiment within the range of the same configuration as that of the semiconductor device A10.

### Second Embodiment

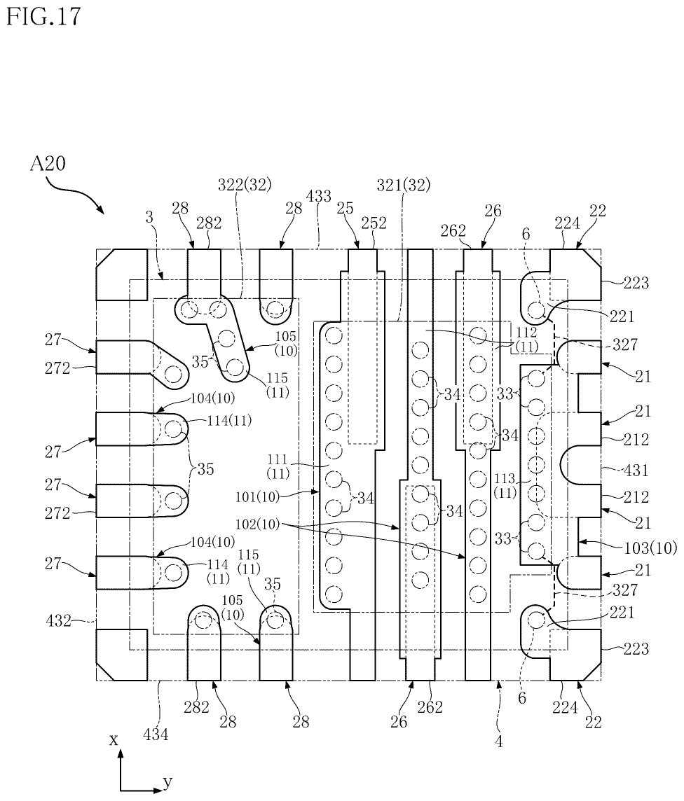

FIG. 17 shows a semiconductor device A20 according to a second embodiment of the present disclosure. FIG. 17 is a plan view showing the semiconductor device A20. For convenience of understanding, FIG. 17 shows the semiconductor element 3 and the sealing resin 4 in phantom. In FIG. 17, the semiconductor element 3 and the sealing resin 4 are indicated by imaginary lines (two-dot chain lines).

The semiconductor device A20 of the present embodiment includes third wires 327 instead of the first wire 325 provided on the semiconductor layer 32 (the semiconductor element 3) in the above embodiment. The paths of the third wires 327 are simplified and indicated by dotted lines. Each of the third wires 327 is electrically connected to one of the first conductive sections 6 and one of the first electrodes 33. In the present embodiment, the third wires 327 are provided at two locations on the first side and the second side in the first direction x, corresponding to the two second terminal sections 22 arranged on the first side and the second side in the first direction x with respect to the first terminal sections 21. The third wire 327 on the first side in the first direction x is electrically connected to the first conductive section 6 on the first side in the first direction x and the first electrode 33 located at the end on the first side in the first direction x among the first electrodes 33. The third wire 327 on the second side in the first direction x is electrically connected to the first conductive section 6 on the second side in the first direction x and the first electrode 33 located at the end on the second side in the first direction x among the first electrodes 33.

According to the semiconductor device A20 in the present embodiment, the first conductive sections 6 are each located closer to a corner of the package made of the sealing resin 4 than are the first electrodes 33. Thus, the internal stress is larger at the bonding portion of each first conductive section 6 to one of the second terminal sections 22 than at the bonding portion of each first electrode 33 to the third main section 103 (the third obverse surface 113). Accordingly, the internal stress at the bonding portion of each first electrode 33 electrically connected to the switching circuit 321 (the circuit section) can be reduced by providing the first conductive sections 6 near some corners of the sealing resin 4. This makes it possible to improve the bonding reliability of the semiconductor element 3 provided by flip-chip mounting.

In the semiconductor device A20, the two second terminal sections 22 are arranged on the first side and the second side in the first direction x, respectively, relative to the first terminal sections 21. Further, the two first conductive sections 6 are each provided between one of the two second terminal sections 22 and the element first surface 320 of the semiconductor layer 32. Such a configuration can reduce the internal stress of the bonding portions of the first electrodes 33 located at the respective ends in the alignment direction (the first direction x) among the plurality of first electrodes 33. This is more preferable for improving the bonding reliability of the semiconductor element 3.

The first electrodes 33 are aligned in the first direction x. Each of the first conductive sections 6 overlaps with the first electrodes 33 as viewed in the first direction x. Such a configuration can efficiently reduce the internal stress of the bonding portions of the first electrodes 33.

The semiconductor layer 32 (the semiconductor element 3) of the semiconductor device A20 has a third wire 327 electrically connected to one of the first conductive sections 6 and one of the first electrodes 33. With such a configuration, the second terminal section 22 connected to the first conductive section 6 and the first terminal section 21 electrically connected to the first electrode 33 are used to electrically measure the path of the first conductive section 6, the first electrode 33, and the third wire 327, whereby a change in the bonding state of the bonding portion of the first conductive section 6 can be detected as a change in resistance value. This makes it possible to check the bonding states of the bonding portions of the two first conductive sections 6. This leads to an improvement of the bonding reliability of the semiconductor device A20 having the semiconductor element 3 provided by flip-chip mounting.

The semiconductor device according to the present disclosure is not limited to the above embodiments. Various design changes can be made to the specific configurations of the elements of the semiconductor device according to the present disclosure.

Although the above embodiments have been described with an example where the first side surfaces 212 of the first terminal sections 21 are flush with the first resin side surface 431, the present disclosure is not limited to this. For example, each of the first terminal sections 21 (the first side surfaces 212) may have a shape protruding outward from the sealing resin 4. Alternatively, a portion of the tip of each first terminal section 21 in the second direction y and a portion of the sealing resin 4 around the portion of the tip may be cut away, so that the first side surface 212 is located inward of the sealing resin 4 from the first resin side surface 431 as viewed in the thickness direction z. The second side surface 223 and the third side surface 224 of each second terminal section 22 can be varied in the same manner as the first side surfaces 212 of the first terminal sections 21 described above. Each of the second terminal sections 22 (the second side surfaces 223 and the third side surfaces 224) may have a shape protruding outward from the sealing resin 4. Alternatively, each of the second side surfaces 223 may be located inward of the sealing resin 4 from the first resin side surface 431 as viewed in the thickness direction z, and each of the third side surfaces 224 may be located inward of the sealing resin 4 from the second resin side surface 433 (434) as viewed in the thickness direction z.

Although the above embodiments describe the configuration where the second terminal sections 22 and the first conductive sections 6 connected to the second terminal sections 22 are arranged at the corners of the sealing resin 4 on the first side in the second direction y and on the respective sides in the first direction x, a second terminal section 22 and a first conductive section 6 may be arranged at each of the four corners of the sealing resin 4.

The present disclosure includes the embodiments described in the following clauses.
Clause 1.

A semiconductor device comprising:
a lead including an obverse surface facing a first side in a thickness direction;
a semiconductor element including a circuit section, an element first surface facing the obverse surface in the thickness direction, and a plurality of first electrodes provided on the element first surface, the plurality of first electrodes being connected to the obverse surface;
a sealing resin covering a portion of the lead and the semiconductor element; and
a first conductive section,
wherein the lead includes a plurality of first terminal sections aligned in a first direction perpendicular to the thickness direction, and a second terminal section arranged closer to an end of the sealing resin in the first direction than are the plurality of first terminal sections,
each of the plurality of first electrodes is electrically connected to the circuit section,
each of the plurality of first terminal sections is electrically connected to the circuit section via at least one of the plurality of first electrodes,
the first conductive section is interposed between the second terminal section and the element first surface and connected to the second terminal section and the element first surface, and
the first conductive section is insulated from the circuit section.
Clause 2.

The semiconductor device according to clause 1, wherein the lead includes two second terminal sections arranged on a first side and a second side in the first direction, respectively, relative to the plurality of first terminal sections, and
the semiconductor device further comprises two first conductive sections each arranged between one of the two second terminal sections and the element first surface.
Clause 3.

The semiconductor device according to clause 2, wherein the semiconductor element includes a first wire electrically connected to the two first conductive sections.
Clause 4.

The semiconductor device according to any of clauses 1 to 3, wherein each of the plurality of first terminal sections includes a first mounting surface facing a second side in the thickness direction, and a first side surface facing in a second direction perpendicular to the thickness direction and the first direction, and
the first mounting surface and the first side surface are exposed from the sealing resin.
Clause 5.

The semiconductor device according to clause 4, wherein the sealing resin includes a first resin side surface located at an end in the second direction and facing in the second direction, and
the first side surface is flush with the first resin side surface, or is located inward of the sealing resin from the first resin side surface as viewed in the thickness direction.
Clause 6.

The semiconductor device according to clause 5, wherein the second terminal section includes a second mounting surface facing the second side in the thickness direction, a second side surface facing in the second direction, and a third side surface facing in the first direction, and
the second mounting surface, the second side surface, and the third side surface are exposed from the sealing resin.
Clause 7.

The semiconductor device according to clause 6, wherein the sealing resin includes a second resin side surface located at an end in the first direction and facing in the first direction,
the second side surface is flush with the first resin side surface, or is located inward of the sealing resin from the first resin side surface as viewed in the thickness direction, and
the third side surface is flush with the second resin side surface, or is located inward of the sealing resin from the second resin side surface as viewed in the thickness direction.
Clause 8.

The semiconductor device according to any of clauses 1 to 7, wherein the plurality of first electrodes are aligned in the first direction.
Clause 9.

The semiconductor device according to clause 8, wherein the first conductive section overlaps with the plurality of first electrodes as viewed in the first direction.
Clause 10.

The semiconductor device according to clause 1, wherein the lead includes two second terminal sections arranged near a first side in the first direction relative to the plurality of first terminal sections,
the semiconductor device further comprises two first conductive sections each arranged between one of the two second terminal sections and the element first surface, and
the semiconductor element includes a second wire electrically connected to the two first conductive sections.
Clause 11.

The semiconductor device according to clause 10, wherein each of the plurality of first terminal sections includes a first mounting surface facing a second side in the thickness direction, and a first side surface facing in a second direction perpendicular to the thickness direction and the first direction, and
the first mounting surface and the first side surface are exposed from the sealing resin.
Clause 12.

The semiconductor device according to clause 11, wherein the sealing resin includes a first resin side surface located at an end in the second direction and facing in the second direction, and
the first side surface is flush with the first resin side surface, or is located inward of the sealing resin from the first resin side surface as viewed in the thickness direction.
Clause 13.

The semiconductor device according to clause 12, wherein each of the second terminal sections includes a third mounting surface facing the second side in the thickness direction, and a fourth side surface facing in the first direction or the second direction, and
the third mounting surface and the fourth side surface are exposed from the sealing resin.
Clause 14.

The semiconductor device according to clause 13, wherein the sealing resin includes a second resin side surface located at an end in the first direction and facing in the first direction, and
the fourth side surface is flush with one of the first resin side surface and the second resin side surface, or is located inward of the sealing resin from one of the first resin side surface and the second resin side surface as viewed in the thickness direction.
Clause 15.

A semiconductor device comprising:
a lead including an obverse surface facing a first side in a thickness direction;
a semiconductor element including a circuit section, an element first surface facing the obverse surface in the thickness direction, and a plurality of first electrodes provided on the element first surface, the plurality of first electrodes being connected to the obverse surface; and
a sealing resin covering a portion of the lead and the semiconductor element,
wherein the lead includes a plurality of first terminal sections aligned in a first direction perpendicular to the thickness direction, and a second terminal section arranged closer to an end of the sealing resin in the first direction than are the plurality of first terminal sections,
each of the plurality of first electrodes is electrically connected to the circuit section,
each of the plurality of first terminal sections is electrically connected to the circuit section via at least one of the plurality of first electrodes,
the semiconductor device further comprises a second conductive section interposed between the third terminal section and the element first surface and connected to the second terminal section and the element first surface, and
the semiconductor element includes a third wire electrically connected to one of the plurality of first electrodes and the second conductive section.

REFERENCE NUMERALS

| | |
|---|---|
| A10, A11, A20: Semiconductor device | 1: Lead |
| 10: Main section | 101: First main section |
| 102: Second main section | 103: Third main section |
| 104: Fourth main section | 105: Fifth main section |
| 11: Obverse surface | 111: First obverse surface |
| 112: Second obverse surface | 113: Third obverse surface |
| 114: Fourth obverse surface | 115: Fifth obverse surface |
| 12: Reverse surface | 121: First reverse surface |
| 122: Second reverse surface | 21: First terminal section |
| 211: First mounting surface | 212: First side surface |
| 22: Second terminal section | 221: Extending portion |
| 222: Second mounting surface | 223: Second side surface |
| 224: Third side surface | 23: Second terminal section |
| 231: Extending portion | 232: Third mounting surface |
| 233: Fourth side surface | 25, 26, 27, 28: Terminal section |
| 251, 261, 271, 281: Mounting surface | |
| 252, 262, 272, 282: Side surface | |
| 3: Semiconductor element | 31: Semiconductor substrate |
| 32: Semiconductor layer | 320: Element first surface |
| 321: Switching circuit | 322: Control circuit |
| 325: First wire | 326: Second wire |
| 327: Third wire | 33: First electrode |
| 331: Bonding layer | 34, 35: Electrode |
| 4: Sealing resin | 41: Resin obverse surface |
| 42: Resin reverse surface | 431, 432: First resin side surface |
| 433, 434: Second resin side surface | 43, 444: Second resin intermediate surface |
| 451, 452: First resin inner side surface | 453, 454: Second resin inner side surface |
| 6: First conductive section | 61: Bonding layer |
| x: First direction | y: Second direction |
| z: Thickness direction | |

1. A semiconductor device comprising:
a lead including an obverse surface facing a first side in a thickness direction;
a semiconductor element including a circuit section, an element first surface facing the obverse surface in the thickness direction, and a plurality of first electrodes provided on the element first surface, the plurality of first electrodes being connected to the obverse surface; and
a sealing resin covering a portion of the lead and the semiconductor element; and
a first conductive section,
wherein the lead includes a plurality of first terminal sections aligned in a first direction perpendicular to the thickness direction, and a second terminal section arranged closer to an end of the sealing resin in the first direction than are the plurality of first terminal sections,
each of the plurality of first electrodes is electrically connected to the circuit section,
each of the plurality of first terminal sections is electrically connected to the circuit section via at least one of the plurality of first electrodes,
the first conductive section is interposed between the second terminal section and the element first surface and connected to the second terminal section and the element first surface, and
the first conductive section is insulated from the circuit section.

2. The semiconductor device according to claim 1, wherein the lead includes two second terminal sections arranged on a first side and a second side in the first direction, respectively, relative to the plurality of first terminal sections, and
the semiconductor device further comprises two first conductive sections each arranged between one of the two second terminal sections and the element first surface.

3. The semiconductor device according to claim 2, wherein the semiconductor element includes a first wire electrically connected to the two first conductive sections.

4. The semiconductor device according to claim 1, wherein each of the plurality of first terminal sections includes a first mounting surface facing a second side in the thickness direction, and a first side surface facing in a second direction perpendicular to the thickness direction and the first direction, and
the first mounting surface and the first side surface are exposed from the sealing resin.

5. The semiconductor device according to claim 4, wherein the sealing resin includes a first resin side surface located at an end in the second direction and facing in the second direction, and
the first side surface is flush with the first resin side surface, or is located inward of the sealing resin from the first resin side surface as viewed in the thickness direction.

6. The semiconductor device according to claim 5, wherein the second terminal section includes a second mounting surface facing the second side in the thickness direction, a second side surface facing in the second direction, and a third side surface facing in the first direction, and
the second mounting surface, the second side surface, and the third side surface are exposed from the sealing resin.

7. The semiconductor device according to claim 6, wherein the sealing resin includes a second resin side surface located at an end in the first direction and facing in the first direction,
the second side surface is flush with the first resin side surface, or is located inward of the sealing resin from the first resin side surface as viewed in the thickness direction, and
the third side surface is flush with the second resin side surface, or is located inward of the sealing resin from the second resin side surface as viewed in the thickness direction.

8. The semiconductor device according to claim 1, wherein the plurality of first electrodes are aligned in the first direction.

9. The semiconductor device according to claim 8, wherein the first conductive section overlaps with the plurality of first electrodes as viewed in the first direction.

10. The semiconductor device according to claim 1, wherein the lead includes two second terminal sections arranged near a first side in the first direction relative to the plurality of first terminal sections,
the semiconductor device further comprises two first conductive sections each arranged between one of the two second terminal sections and the element first surface, and
the semiconductor element includes a second wire electrically connected to the two first conductive sections.

11. The semiconductor device according to claim 10, wherein each of the plurality of first terminal sections includes a first mounting surface facing a second side in the thickness direction, and a first side surface facing in a second direction perpendicular to the thickness direction and the first direction, and
the first mounting surface and the first side surface are exposed from the sealing resin.

12. The semiconductor device according to claim 11, wherein the sealing resin includes a first resin side surface located at an end in the second direction and facing in the second direction, and
the first side surface is flush with the first resin side surface, or is located inward of the sealing resin from the first resin side surface as viewed in the thickness direction.

13. The semiconductor device according to claim 12, wherein each of the second terminal sections includes a third mounting surface facing the second side in the thickness direction, and a fourth side surface facing in the first direction or the second direction, and
the third mounting surface and the fourth side surface are exposed from the sealing resin.

14. The semiconductor device according to claim 13, wherein the sealing resin includes a second resin side surface located at an end in the first direction and facing in the first direction, and
the fourth side surface is flush with one of the first resin side surface and the second resin side surface, or is located inward of the sealing resin from one of the first resin side surface and the second resin side surface as viewed in the thickness direction.
